(19) United States
(12) Patent Application Publication
(10) Pub. No.: US 2026/0007046 A1
(43) Pub. Date: Jan. 1, 2026

(54) DISPLAY APPARATUS AND ELECTRONIC DEVICE INCLUDING THE SAME

(71) Applicant: Samsung Display Co., Ltd., Yongin-si (KR)

(72) Inventors: Donghoo Kim, Yongin-si (KR); Hwiseong Kim, Yongin-si (KR); Jaeman Lee, Yongin-si (KR); Jihun Park, Yongin-si (KR); Maengha Lee, Yongin-si (KR)

(21) Appl. No.: 19/091,241

(22) Filed: Mar. 26, 2025

(30) Foreign Application Priority Data
Jun. 26, 2024 (KR) 10-2024-0083972

(51) Int. Cl. H10K 59/80; H10K 59/127

(52) U.S. Cl. CPC H10K 59/873; H10K 59/1275; H10K 59/8722; H10K 59/879

(57) ABSTRACT

A display apparatus includes a first substrate including a display area including a display layer, and a peripheral area which is adjacent to the display area, an encapsulation layer which covers the display layer and extends to the peripheral area, a filler pattern which is protruded from the encapsulation layer in a direction away from the first substrate, within the peripheral area, a second substrate facing the first substrate with the encapsulation layer therebetween, a sealing member which combines the first substrate to the second substrate, the sealing member together with the first substrate and the second substrate providing an inner space of the display apparatus in which the display layer, the encapsulation layer and the filler pattern are disposed, and a filling member which fills the inner space.

This application claims priority to Korean Patent Application No. 10-2024-0083972, filed on Jun. 26, 2024, and all the benefits accruing therefrom under 35 U.S.C. § 119, the disclosure of which is incorporated by reference herein in its entirety.

### BACKGROUND

### 1. Field

One or more embodiments relate to an electronic apparatus. More particularly, one or more embodiments relate to a display apparatus and an electronic device having the same.

### 2. Description of the Related Art

Mobile electronic devices have become widely used. In addition to small electronic devices such as mobile phones, tablet personal computers (PCs) have become broadly used as mobile electronic devices.

Such mobile electronic devices include display apparatuses to provide a user with visual information such as an image or a video, in order to support various functions. With the miniaturization of various components for driving a display apparatus, the importance of the display apparatus for an electronic device has continually increased. As an example, a structure whereby a flat display apparatus may be bent to have a predetermined angle has been developed.

### SUMMARY

One or more embodiments include a display apparatus including a structure in which a filling member disposed between two substrates does not spill out and compactly fills the space between the substrates in a process in which the two substrates are coupled to each other.

However, this objective is just an example and the scope of the disclosure is not limited thereto.

Additional aspects will be set forth in part in the description which follows and, in part, will be apparent from the description, or may be learned by practice of the presented embodiments of the disclosure.

According to one or more embodiments, a display apparatus including a display area and a peripheral area includes a first substrate, a display layer disposed on the first substrate and including a pixel circuit layer and a light-emitting diode layer disposed on the pixel circuit layer, an encapsulation layer disposed on the pixel circuit layer to cover the light-emitting diode layer, a second substrate disposed on the first substrate to be spaced apart from the encapsulation layer, a sealing member supporting the second substrate with respect to the first substrate, a filling member filled between the first substrate and the second substrate, and a first structure supported by the encapsulation layer in the peripheral area and protruding in a direction toward the second substrate.

The peripheral area may include a corner portion, a plurality of first peripheral areas arranged to be spaced apart from each other, and a plurality of second peripheral areas connected between the plurality of first peripheral areas, and at least a portion of the first structure may be arranged in at least one of the plurality of first peripheral areas.

In a plan view, the first structure may include a semi-circular shape which is convex toward the corner portion.

The first structure may include a first portion extending along a first line which is a virtual line arranged in the peripheral area to surround the display area and a plurality of second portions extending along a second line which is a virtual line arranged in the peripheral area to surround the display area. The first line may surround the second line. The plurality of second portions may be spaced apart from each other in at least one of the plurality of first peripheral areas.

The first structure may further include a plurality of third portions extending along a third line which is a virtual line arranged in the peripheral area to surround the display area. The second line may surround the third line. The plurality of third portions may be spaced apart from each other in at least one of the plurality of first peripheral areas.

The first structure may further include a plurality of fourth portions extending along a fourth line which is a virtual line arranged in the peripheral area to surround the display area. The third line may surround the fourth line. The plurality of fourth portions may be spaced apart from each other in at least one of the plurality of first peripheral areas.

The first structure may further include a plurality of fifth portions arranged along the third line in at least one of the plurality of second peripheral areas.

The first structure may further include a plurality of fifth portions extending in a direction crossing each of the second line and the third line in at least one of the plurality of second peripheral areas.

The display apparatus may further include a micro lens array (MLA) layer disposed on the encapsulation layer and including a plurality of lenses.

A material of the first structure may be same as a material of the MLA layer.

According to one or more embodiments, a display apparatus including a display area and a peripheral area includes a lower portion including a first substrate, a display layer disposed on the first substrate, an encapsulation layer disposed on the display layer, and a first structure supported by the encapsulation layer in the peripheral area and an upper portion including a second substrate, a sealing member disposed on a surface of the second substrate in the peripheral area, and a filling member disposed on a surface of the second substrate and sealed by the sealing member, where the first structure protrudes in a direction toward the second substrate and is apart from the second substrate.

The peripheral area may include a corner portion, a plurality of first peripheral areas arranged to be spaced apart from each other, and a plurality of second peripheral areas connected between the plurality of first peripheral areas, and at least a portion of the first structure may be arranged in at least one of the plurality of first peripheral areas.

In a plan view, the first structure may include a semi-circular shape which is convex toward the corner portion.

The first structure may include a first portion extending along a first line which is a virtual line arranged in the peripheral area to surround the display area and a plurality of second portions extending along a second line which is a virtual line arranged in the peripheral area to surround the display area. The first line may surround the second line. The plurality of second portions may be spaced apart from each other in at least one of the plurality of first peripheral areas.

The first structure further may include a plurality of third portions extending along a third line which is a virtual line arranged in the peripheral area to surround the display area. The second line may surround the third line. The plurality of third portions may be spaced apart from each other in at least one of the plurality of first peripheral areas.

The first structure may further include a plurality of fourth portions extending along a fourth line which is a virtual line arranged in the peripheral area to surround the display area. The third line may surround the fourth line. The plurality of fourth portions may be spaced apart from each other in at least one of the plurality of first peripheral areas.

The first structure may further include a plurality of fifth portions arranged along the third line in at least one of the plurality of second peripheral areas.

The first structure may further include a plurality of fifth portions extending in a direction crossing each of the second line and the third line in at least one of the plurality of second peripheral areas.

The display apparatus may further include a micro lens array (MLA) layer disposed on the encapsulation layer and including a plurality of lenses.

A material of the first structure may be same as a material of the MLA layer.

According to one or more embodiments, an electronic device includes a display apparatus including a display area and a peripheral area, where the display apparatus includes a first substrate, a display layer disposed on the first substrate and including a pixel circuit layer and a light-emitting diode layer disposed on the pixel circuit layer, an encapsulation layer disposed on the pixel circuit layer to cover the light-emitting diode layer, a second substrate disposed on the first substrate to be spaced apart from the encapsulation layer, a sealing member supporting the second substrate with respect to the first substrate, a filling member filled between the first substrate and the second substrate, and a first structure supported by the encapsulation layer in the peripheral area and protruding in a direction toward the second substrate.

### BRIEF DESCRIPTION OF THE DRAWINGS

The above and other aspects, features, and advantages of embodiments of the disclosure will be more apparent from the following description taken in conjunction with the accompanying drawings, in which:

FIGS. 1 and 2 are schematic plan views of a display apparatus according to an embodiment;

FIG. 3 is a schematic circuit diagram of a pixel of a display apparatus according to an embodiment;

FIGS. 4 and 5 are schematic cross-sectional views of a display apparatus according to an embodiment;

FIG. 6 is a schematic cross-sectional view of a portion of a display apparatus according to an embodiment;

FIG. 7 is a schematic plan view of a portion of a display apparatus according to an embodiment;

FIG. 8 is a schematic plan view of a portion of a display apparatus according to an embodiment;

FIG. 9 is a schematic plan view of a portion of a display apparatus according to an embodiment; and

FIG. 10 is a schematic perspective view of an electronic device according to an embodiment.

### DETAILED DESCRIPTION

Reference will now be made in detail to embodiments, examples of which are illustrated in the accompanying drawings, where like reference numerals refer to like elements throughout. In this regard, the present embodiments may have different forms and should not be construed as being limited to the descriptions set forth herein. Accordingly, the embodiments are merely described below, by referring to the figures, to explain aspects of the present description.

As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

While the disclosure is capable of having various modifications and alternative forms, embodiments thereof are shown by way of example in the drawings and will herein be described in detail. The effects and characteristics of the disclosure and methods of achieving the same will become apparent by referring to the embodiments described below in detail with reference to the drawings. However, the disclosure is not limited to the embodiments disclosed hereinafter and may be realized in various forms.

Hereinafter, embodiments will be described in detail by referring to the accompanying drawings, where, when describing the accompanying drawings, elements which are the same as or corresponding to each other will be assigned the same reference numerals, repeated descriptions thereof will not be given. Within the Figures and the text of the disclosure, a reference number indicating a singular form of an element may also be used to reference a plurality of the singular element.

In the embodiments described hereinafter, the terms “first,” “second,” etc. are used to distinguish an element from another and are not used as a restrictive sense.

The terminology used herein is for the purpose of describing particular embodiments only and is not intended to be limiting. As used herein, the singular expressions “a,” “an,” and “the” are intended to include the plural forms as well, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise.

It will be further understood that the terms “comprises” and/or “comprising” used herein specify the presence of stated features or elements, but do not preclude the presence or addition of one or more other features or elements.

It will be understood that when a layer, region, or element is referred to as being related to another layer such as being “on” another layer, area, or element, it can be directly or indirectly formed on the other layer, region, or element. That is, for example, intervening layers, regions, or elements may be present. In contrast, when a layer, region, or element is referred to as being related to another layer such as being “directly on” another layer, area, or element, no intervening layer, regio or element is present therebetween.

Also, for convenience of explanation, elements in the drawings may have exaggerated or reduced sizes. For example, sizes and thicknesses of the elements in the drawings are randomly indicated for convenience of explanation, and thus, the disclosure is not necessarily limited to the illustrations of the drawings.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

In the embodiments hereinafter, the x-axis, the y-axis and the z-axis are not limited to three axes of the rectangular coordinate system, and may be interpreted in a broader sense. For example, the x-axis, the y-axis, and the z-axis may be perpendicular to one another, or may represent different directions which are not perpendicular to one another.

When an embodiment may be implemented differently, a specific process order may be performed differently from the described order. For example, two consecutively described processes may be performed substantially at the same time or performed in an order opposite to the described order.

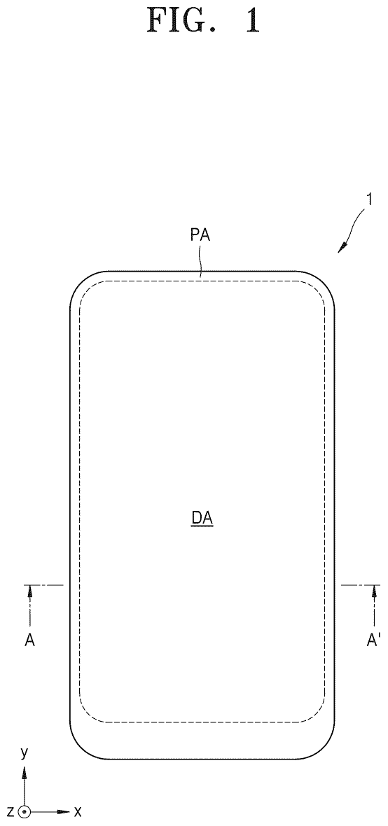

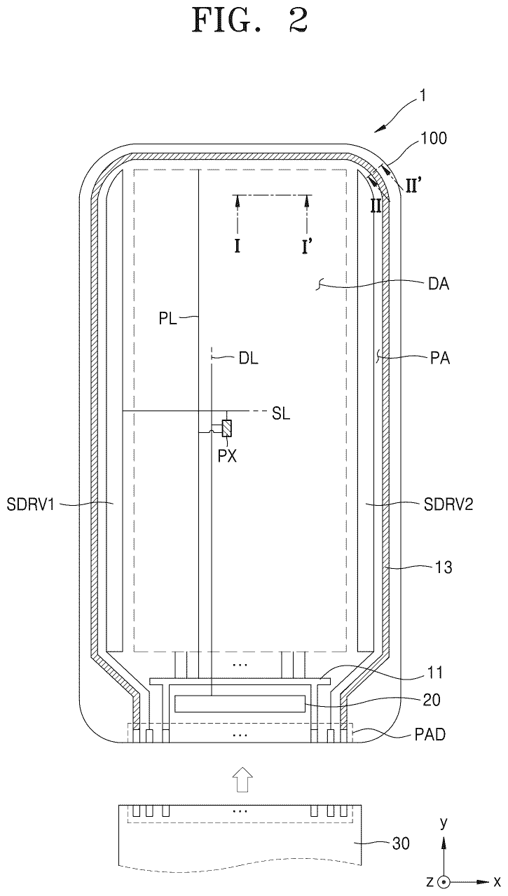

FIGS. 1 and 2 are schematic plan views of a display apparatus 1 according to an embodiment.

Referring to FIG. 1, the display apparatus 1 may include a display area DA and a peripheral area PA which is outside (or at an outer portion of) the display area DA. However, the display apparatus 1 may include a first substrate 100 (see FIG. 2). As such, it may be understood that the first substrate 100 may include the display area DA and the peripheral area PA. Alternatively, it may be understood that the display area DA and the peripheral area PA are defined on the first substrate 100.

The display area DA may be an area (e.g., a planar area) for displaying an image, and a plurality of pixels PX may be arranged in the display area DA. The display area DA may have other planar shapes, such as a circular shape, an oval shape, a polygonal shape, a shape of a predetermined figure, etc. For example, FIG. 1 illustrates that the display area DA has approximately a rectangular planar shape with round edges.

The peripheral area PA may be arranged outside the display area DA, such as to be closer to an outer edge of the display apparatus 1 (or first substrate 100) than the display area DA. The peripheral area PA may be arranged to extend along and/or surround at least a portion of the display area DA.

Hereinafter, an organic light-emitting display apparatus is described as an example of the display apparatus 1 according to an embodiment. However, the display apparatus 1 according to the disclosure is not limited thereto. According to an embodiment, the display apparatus 1 according to the disclosure may include an inorganic light-emitting display apparatus, an inorganic electroluminescent (EL) display apparatus, or a quantum dot light-emitting display apparatus. In an embodiment, for example, an emission layer of a display element included in the display apparatus 1 may include an organic material, an inorganic material, quantum dots, an organic material and quantum dots, or an inorganic material and quantum dots.

Referring to FIG. 2, the display apparatus 1 may include the first substrate 100. Various elements included in the display apparatus 1 may be disposed on the first substrate 100. The first substrate 100 may include the display area DA and the peripheral area PA which is outside the display area DA. In this specification, that an element is located in the display area DA may denote that the element is disposed on the first substrate 100 in the display area DA or is disposed on the first substrate 100 to overlap the display area DA. Likewise, in this specification, that an element is located in the peripheral area PA may denote that the element is disposed on the first substrate 100 in the peripheral area PA or is disposed on the first substrate 100 to overlap the peripheral area PA.

A pixel PX which is provided in plural such as a plurality of pixels PX may be arranged in the display area DA. Each pixel PX may include a light-emitting element such as a light-emitting diode or an organic light-emitting diode. Each pixel PX may emit, for example, red, green, blue, or white light.

Pixel circuits configured to drive the pixels PX may be connected to signal lines or a voltage line configured to control turning on/off, the brightness, etc. of the light-emitting diode. In an embodiment, for example, FIG. 2 illustrates a scan line SL extending in a first direction (for example, an x-axis direction) and a data line DL extending in a second direction (for example, a y-axis direction) as the signal lines and a driving voltage line PL as the voltage line. A thickness of the display apparatus 1 and various components or layers thereof may be defined along a third direction (for example, a z-axis direction).

The peripheral area PA may be a non-display area in which an image is not displayed. The peripheral area PA may be adjacent to the display area DA at portions thereof. In an embodiment, the peripheral area PA may surround an entirety of the display area DA in a plan view. The peripheral area PA may include outer circuits which drive or are configured to drive the pixels PX. In an embodiment, for example, in the peripheral area PA, a first scan driver SDRV1, a second scan driver SDRV2, a data driver 20, a terminal portion PAD as a pad area, a driving voltage supply line 11, and a common voltage supply line 13 may be arranged.

The first scan driver SDRV1 may be configured to apply, through the scan line SL, a scan signal to each of the pixel circuits to drive the pixels PX. The second scan driver SDRV2 may be located on the opposite side to the first scan driver SDRV1 with respect to the display area DA and may be approximately in parallel with the first scan driver SDRV1. Some of the pixel circuits of the pixels PX arranged in the display area DA may be electrically connected to the first scan driver SDRV1, and the others of the pixel circuits may be electrically connected to the second scan driver SDRV2.

The data driver 20 may include an integrated circuit (for example, a driving chip) configured to drive the display apparatus 1. The integrated circuit may include a data driving integrated circuit configured to generate a data signal. However, the disclosure is not limited thereto. The data driver 20 may include a plurality of terminals. The data driver 20 may be, through the terminals, electrically connected to an electrical component such as a printed circuit board 30 attached onto a side of the display apparatus 1. According to an embodiment, the data driver 20 may be provided on the printed circuit board 30. The electrical component may be connected to a display panel (e.g., represented by the first substrate 100 in FIG. 2) of the display apparatus 1, at the pad area of the display panel.

The terminal portion PAD may be disposed at a side of the first substrate 100. The terminal portion PAD may not be covered by an insulating layer and may be exposed to outside the insulating layer for connection of the printed circuit board 30 to terminals or pads of the terminal portion PAD.

A controller (not shown) may be disposed on the printed circuit board 30. The controller may generate a control signal to be transmitted to the first scan driver SDRV1 and the second scan driver SDRV2. Also, the controller may supply a driving voltage ELVDD to the driving voltage supply line 11 and a common voltage ELVSS to the common voltage supply line 13. The driving voltage ELVDD may be applied to the pixel circuits of the pixels PX through the driving voltage line PL connected to the driving voltage supply line 11, and the common voltage ELVSS may be applied to an opposite electrode of the light-emitting diode connected to the common voltage supply line 13. The driving voltage supply line 11 may extend in the first direction (for example, the x-axis direction) at a lower portion of the display area DA. The common voltage supply line 13 may have a loop shape having an open side and may partially surround the display area DA.

The controller may generate a data signal, and the generated data signal may be transmitted by the data driver 20 to the data line DL. The data signal may be sequentially transmitted to the pixels PX arranged in the same column, through the data lines DL extending in the second direction (for example, the y-axis direction). Also, the controller may generate a touch driving signal transmitted to each of sensor electrodes of a touch sensor layer.

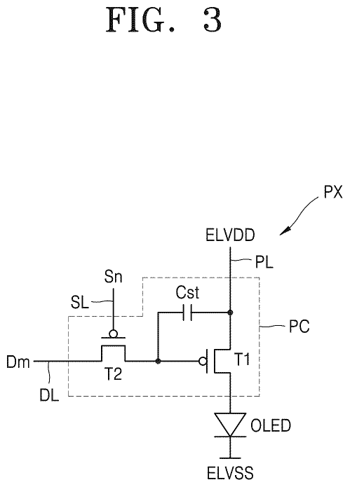

FIG. 3 is a schematic circuit diagram showing a pixel PX of a display apparatus 1 according to an embodiment.

Referring to FIG. 3, the pixel circuit PC may be connected to a light-emitting element, such as a light-emitting diode or an organic light-emitting diode OLED, and may realize light emission of the pixels PX. The pixel circuit PC may include a driving thin-film transistor T1, a switching thin-film transistor T2, and a storage capacitor Cst. The switching thin-film transistor T2 may be connected to a scan line SL and a data line DL and may be configured to transmit a data signal Dm input through the data line DL, to the driving thin-film transistor T1, according to a scan signal Sn input through the scan line SL.

The storage capacitor Cst may be connected to the switching thin-film transistor T2 and a driving voltage line PL and may store a voltage corresponding to the difference between a voltage received from the switching thin-film transistor T2 and a driving voltage ELVDD supplied to the driving voltage line PL.

The driving thin-film transistor T1 may be connected to the driving voltage line PL and the storage capacitor Cst and may be configured to control a driving current flowing from the driving voltage line PL through the organic light-emitting diode OLED according to a value of the voltage stored in the storage capacitor Cst. The organic light-emitting diode OLED may emit light having a certain brightness according to the driving current.

However, the pixel circuit PC is not limited to the number of thin-film transistors and storage capacitors and the circuit design of the thin-film transistors and the storage capacitors, described with reference to FIG. 3, and may be variously modified.

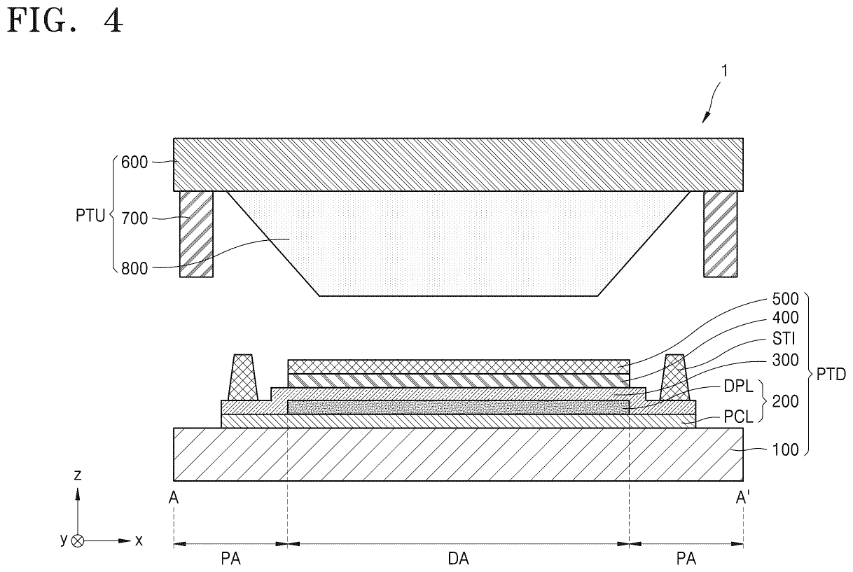

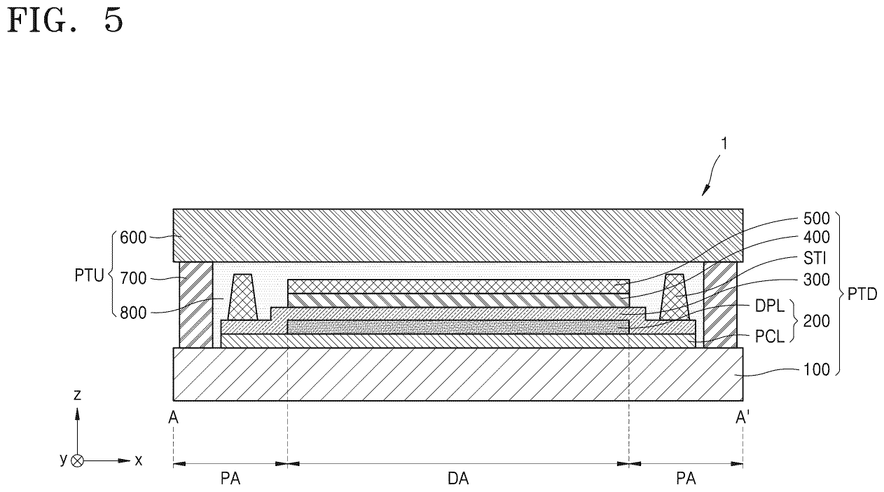

FIGS. 4 and 5 are schematic cross-sectional views of the display apparatus 1 according to an embodiment. The cross-sectional views are taken along line A-A′ in FIG. 1.

Referring to FIGS. 4 and 5, the display apparatus 1 may include the first substrate 100, a display layer 200, an encapsulation layer 300, a color filter layer 400, a micro lens array (MLA) layer 500 as a lens array layer, a first structure ST1 as a filler pattern, a second substrate 600, a sealing member 700, and a filling member 800.

The display layer 200 may be disposed on the first substrate 100. The display layer 200 may include a pixel circuit layer PCL including one or more pixel circuit PC and a light-emitting diode layer DPL as a light-emitting element layer including one or more light-emitting elements. The pixel circuit layer PCL may be supported by the first substrate 100. The pixel circuit layer PCL may be arranged in the display area DA and in the peripheral area PA. The light-emitting diode layer DPL may be disposed on the pixel circuit layer PCL to be supported by the pixel circuit layer PCL. The light-emitting diode layer DPL may be arranged in the display area DA. The light-emitting layer may be connected to the pixel circuit layer PCL.

The encapsulation layer 300 may be disposed on the first substrate 100. The encapsulation layer 300 may be disposed on the pixel circuit layer PCL to cover the light-emitting diode layer DPL. The encapsulation layer 300 may be arranged in the display area DA and in the peripheral area PA. The light-emitting diode layer DPL may be encapsulated by the encapsulation layer 300.

The color filter layer 400 may be disposed on the first substrate 100. The color filter layer 400 may be disposed on the encapsulation layer 300 to be supported by the encapsulation layer 300. The color filter layer 400 may be arranged in the display area DA.

The MLA layer 500 may be disposed on the first substrate 100 and the encapsulation layer 300. The MLA layer 500 may be disposed on the color filter layer 400 to be supported by the color filter layer 400. The MLA layer 500 may be arranged in the display area DA.

The first structure ST1 may be disposed on the first substrate 100. The first structure ST1 may be disposed on the encapsulation layer 300 to be supported by the encapsulation layer 300. The first structure ST1 may be arranged in the peripheral area PA. The first structure ST1 may be spaced apart from the display area DA. The first structure ST1 may protrude from the encapsulation layer 300 in a direction (for example, a +z-axis direction) away from the first substrate 100. The first structure ST1 may protrude in a direction (for example, the +z-axis direction) toward the second substrate 600 and may be spaced apart from the second substrate 600 along the thickness direction. In an embodiment, for example, in a cross-sectional view, the first structure ST1 may have a ladder shape. However, it is only an example, and the shape of the first structure ST1 may vary.

The second substrate 600 may be disposed on the first substrate 100, such as to face the first substrate 100. The second substrate 600 may be spaced apart from each of the first substrate 100, the display layer 200, the encapsulation layer 300, the color filter layer 400, the MLA layer 500, and the first structure ST1, along the thickness direction of the display apparatus 1. The second substrate 600 may include a transparent member. The second substrate 600 may include a glass material mainly including SiO₂ or may include resins, such as reinforced plastics. Alternatively, the second substrate 600 may include a glass substrate. An image or light may be visible through or pass through the second substrate 600.

The sealing member 700 may be disposed between the first substrate 100 and the second substrate 600 and may support the second substrate 600 with respect to the first substrate 100. The sealing member 700 may be arranged in the peripheral area PA. The sealing member 700 may be arranged to surround the display area DA in the plan view (e.g., a view of a plane defined by the first and second directions crossing each other). Thus, each of the display layer 200, the encapsulation layer 300, the color filter layer 400, the MLA layer 500, the first structure ST1, and the filling member 800 may be sealed by the first substrate 100 together with the second substrate 600 and the sealing member 700.

The filling member 800 may be filled between the first substrate 100, the sealing member 700 and the second substrate 600. The filling member 800 may be disposed in a space formed by (or defined by) an exposed portion of the first substrate 100, the stacked structure (such as the display layer 200, the encapsulation layer 300, the color filter layer 400, the MLA layer 500 and the first structure ST1) thereon, the second substrate 600 and the sealing member 700. The filling member 800 may fill an inner space formed by the first substrate 100, the stacked structure thereon, the second substrate 600, and the sealing member 700. The filling member 800 may be in contact with each of the first substrate 100, the display layer 200, the encapsulation layer 300, the color filter layer 400, the MLA layer 500, the first structure ST1, the second substrate 600, and the sealing member 700. In an embodiment, the filling member 800 may completely fill the inner space. Here, a filler (ST1 and 800 together) may completely fill the inner space, where the filler includes a filler pattern (e.g., the first structure ST1) which is adjacent to the display layer 200 and protruded from the encapsulation layer 300 in a direction toward the second substrate 600, within the peripheral area PA, and a filling member 800 which fills a remainder of the inner space except for a volume occupied by the filler pattern.

The filling member 800 may include a transparent insulating material. In an embodiment, for example, the filling member 800 may include urethane-based resins, epoxy-based resins and acryl-based resins which are organic sealants, or silicon, etc., which are inorganic sealants. Alternatively, the filling member 800 may include, for example, polyimide.

The display apparatus 1 may include a lower portion PTD as a lower stacked structure and an upper portion PTU as an upper stacked structure. FIG. 4 illustrates a state of the display apparatus 1 in which the lower portion PTD and the upper portion PTU are not yet coupled to each other. FIG. 5 illustrates a state of the display apparatus 1 in which the lower portion PTD and the upper portion PTU are coupled to each other. That is, the upper stacked structure is combinable with the lower stacked structure to define the display apparatus 1 having the upper stacked structure combined with the lower stacked structure.

The lower portion PTD may include the first substrate 100 together with the display layer 200 disposed on the first substrate 100, the encapsulation layer 300 disposed on the display layer 200, the color filter layer 400 disposed on the encapsulation layer 300, the MLA layer 500 disposed on the color filter layer 400, and the first structure ST1 supported by the encapsulation layer 300 in the peripheral area PA. The upper portion PTU may include the second substrate 600 together with the sealing member 700 disposed on a surface of the second substrate 600 in the peripheral area PA, and the filling member 800 disposed on a surface of the second substrate 600.

When the lower portion PTD and the upper portion PTU are coupled to each other, the sealing member 700 may be attached onto the first substrate 100 at a side or a surface of the sealing member 700. In an embodiment, for example, the sealing member 700 may include a sealant or frit and may be cured by heat and/or a laser beam to be fixed to each of the first substrate 100 and the second substrate 600 by a cured sealant or a cured frit. Also, when the lower portion PTD and the upper portion PTU are coupled to each other, the filling member 800 may fill the space formed by the first substrate 100, the stacked structure thereon the second substrate 600, and the sealing member 700. Here, the filling member 800 may fill an entirety of the inner space defined by these elements.

The first structure ST1 may be disposed on the encapsulation layer 300. In detail, the first structure ST1 may be disposed on a second inorganic encapsulation layer 330 of the encapsulation layer 300. The first structure ST1 and the MLA layer 500 may include the same material as each other. Thus, the first structure ST1 and the MLA layer 500 may be disposed on the encapsulation layer 300 by the same process as each other. Here, the first structure ST1 and the MLA layer 500 may be in a same layer as each other. As being in a same layer, elements may be formed in a same process and/or include a same material as each other, elements may be respective portions of a same material layer, elements may be on a same layer by forming an interface with a same underlying or overlying layer, etc., without being limited thereto. The protrusions of the first structure ST1 and the protrusions (e.g., lenses) of the MLA layer 500 may together be considered a lens layer or a protrusion layer.

In detail, the first structure ST1 and the MLA layer 500 may be disposed on the encapsulation layer 300 by photoresist processes using the same mask as each other. Thus, the manufacturing cost and manufacturing time of the display apparatus 1 may be reduced. In an embodiment, for example, the first structure ST1 may include urethane-based resins, epoxy-based resins, and acryl-based resins which are organic sealants, or silicon, etc. which are inorganic sealants. Alternatively, the first structure ST1 may include, for example, polyimide.

In an embodiment, the display apparatus 1 may include a first substrate 100 including a display area DA including a pixel circuit layer PCL and a light-emitting diode layer DPL which is connected to the pixel circuit layer PCL, and a peripheral area PA which is adjacent to the display area DA, an encapsulation layer 300 which covers the pixel circuit layer PCL and the light-emitting diode layer DPL and extends to the peripheral area PA, a filler pattern (e.g., the first structure ST1) which is protruded from the encapsulation layer 300 in a direction away from the first substrate 100, within the peripheral area PA, a second substrate 600 facing the first substrate 100 with the encapsulation layer 300 therebetween, a sealing member 700 which combines the first substrate 100 to the second substrate 600 (FIG. 5, for example), the sealing member 700 together with the first substrate 100 and the second substrate 600 providing an inner space of the display apparatus 1 in which the light-emitting diode layer DPL, the pixel circuit layer PCL, the encapsulation layer 300 and the filler pattern are disposed; and a filling member 800 which fills the inner space.

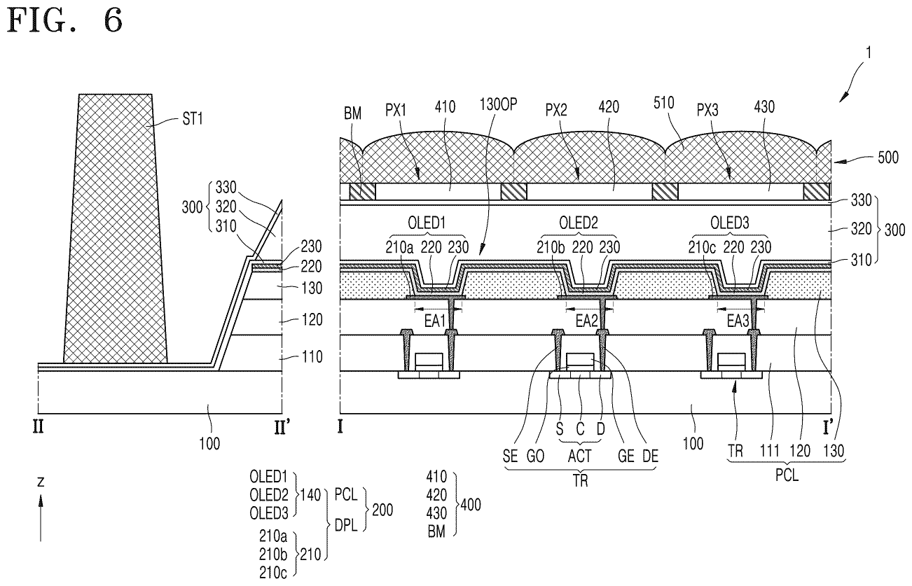

FIG. 6 is a schematic cross-sectional view of a portion of the display apparatus 1 according to an embodiment.

In detail, FIG. 6 may correspond to the portion of the display apparatus 1 of FIG. 2, taken along line I-I′ and line II-II′. Also, the display apparatus 1 illustrated in FIG. 6 may correspond to an enlarged view of the lower portion PTD of the display apparatus 1 illustrated in FIGS. 4 and 5.

Referring to FIG. 6, the display apparatus 1 may include the first substrate 100, the display layer 200, the encapsulation layer 300, the color filter layer 400, the MLA layer 500, and the first structure ST1 as a filler pattern.

The first substrate 100 may have an upper surface extending in an x-axis direction and a y-axis direction, that is, parallel to a plane defined by the first and second directions crossing each other. The first substrate 100 may include a semiconductor material, for example, a group IV semiconductor, a groups III-V compound semiconductor, or a groups II-VI compound semiconductor. That is, the first substrate 100 may include a semiconductor substrate including a semiconductor material. In detail, the first substrate 100 may include silicon. That is, the first substrate 100 may include a silicon substrate (a silicon semiconductor substrate). In an embodiment, for example, the first substrate 100 may include a silicon wafer. The silicon wafer may include a monocrystalline silicon wafer, a polycrystalline silicon wafer, or an amorphous silicon wafer.

Like this, an organic light-emitting diode display apparatus using a semiconductor substrate as the first substrate 100 may be referred to as an organic light-emitting diode on silicon (OLEDoS). The OLEDOS may use the semiconductor substrate as the first substrate 100, and thus, a transistor manufacturing process commonly used in technical fields of semiconductors, may be used in a process of manufacturing the display apparatus. Thus, an ultra-small pixel, which enables the OLEDOS to display an ultra-high resolution image, may be formed and controlled.

According to cases, the type of the first substrate 100 may not be limited to the semiconductor substrate. In an embodiment, for example, the first substrate 100 may include glass, metal, or polymer resins. Also, the first substrate 100 may include polymer resins, such as polyethersulphone, polyacrylate, polyetherimide, polyethylene naphthalate, polyethylene terephthalate, polyphenylene sulfide, polyarylate, polyimide, polycarbonate, or cellulose acetate propionate. However, various modifications may be possible. In an embodiment, for example, the first substrate 100 may have a multi-layered structure of two layers each including the polymer resins described above, and a barrier layer between the two layers which includes an inorganic material (such as silicon oxide, silicon nitride, and/or silicon oxynitride). Hereinafter, a case where the first substrate 100 is a silicon substrate will be mainly described in detail.

The display layer 200 may be disposed on the first substrate 100. The display layer 200 may include the pixel circuit layer PCL and the light-emitting diode layer DPL.

The pixel circuit layer PCL may be disposed on the first substrate 100. The pixel circuit layer PCL may include a plurality of pixel circuits PC respectively corresponding to the plurality of pixels PX described with reference to FIG. 2, and each of the plurality of pixel circuits PC may include the transistor and/or the storage capacitor as described with reference to FIG. 3. In an embodiment, for example, each of the plurality of pixels PX (see FIG. 2) may include a first sub-pixel PX1, a second sub-pixel PX2, and a third sub-pixel PX3.

The pixel circuit layer PCL may include at least one transistor TR, an interlayer insulating layer 111, a via-insulating layer 120, and a pixel-defining layer 130.

The transistor TR may include a gate dielectric layer GO, a gate electrode GE, and an active area ACT. The transistor TR may include, for example, a metal-oxide-semiconductor field effect transistor (MOSFET), but is not limited thereto. According to an embodiment, each of the transistors TR may be isolated from another by a device isolation area arranged between the transistors TR.

The active area ACT as an active pattern of the transistor TR may be arranged in the first substrate 100. The active area ACT may include or be disposed in a thickness portion of the first substrate 100. The active area ACT may be arranged in the first substrate 100 (e.g., within a thickness thereof) to extend in the first direction, for example, the x-axis direction. A portion of a material of the first substrate 100 may be recessed, and the active area ACT may be arranged in the recessed portion of the first substrate 100. The active area ACT may include a channel area C and a drain area D and a source area S which are at both sides of the channel area C along the first direction. Each of the drain area D and the source area S may be an area in the first substrate 100 including a semiconductor material, the area being doped with impurities. The channel area C may overlap the gate electrode GE.

The gate dielectric layer GO may be disposed between the gate electrode GE and the active area ACT. The gate dielectric layer GO may include, for example, an inorganic insulating material, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂).

The gate electrode GE may be disposed on the active area ACT. The gate electrode GE may be arranged across the active area ACT to extend in a direction, for example, the y-axis direction. The channel area C of the transistor TR may be formed in the active area ACT arranged across the gate electrode GE. That is, the gate electrode GE may overlap the channel area C of the transistor TR. The gate electrode GE may be disposed on the gate dielectric layer GO. The gate electrode GE may include a conductive material. In an embodiment, for example, the gate electrode GE may include a semiconductor material, such as metal nitride such as a titanium nitride (TiN) layer, a tantalum nitride (TaN) layer, or a tungsten nitride (WN) layer and/or a metal material such as Al, W, Cu, or Mo or doped polysilicon. The gate electrode GE may include layers or a single layer including the materials described above.

The interlayer insulating layer 111 may be disposed on the first substrate 100 and may cover the transistor TR. The interlayer insulating layer 111 may include at least one of oxide, nitride, and oxynitride. The interlayer insulating layer 111 may include a single layer structure (e.g., a monolayer) or a layered structure.

A drain electrode DE and a source electrode SE may be disposed on the interlayer insulating layer 111. The drain electrode DE and the source electrode SE may be respectively connected to the drain area D and the source area S of the active area ACT through (or at) a contact hole provided in the interlayer insulating layer 111. The drain electrode DE and the source electrode SE may include a highly conductive material. The drain electrode DE and the source electrode SE may include a conductive material including Mo, Al, Cu, Ti, etc. and may include layers or a single layer including the materials described above.

The via-insulating layer 120 may be disposed on the interlayer insulating layer 111. The via-insulating layer 120 may include an organic insulating layer covering upper surfaces of the drain electrode DE and the source electrode SE and having an approximately flat upper surface so as to function as a planarization layer. The via-insulating layer 120 may include, for example, an organic material, such as acryl, benzocyclobutene (BCB), or hexamethyldisiloxane (HMDSO). Although the via-insulating layer 120 is illustrated as a single layer but is not limited thereto. The via-insulating layer 120 may be formed of a plurality of layers.

The pixel-defining layer 130 may be disposed on the via-insulating layer 120. The pixel-defining layer 130 may include an organic insulating material and/or an inorganic insulating material. The pixel-defining layer 130 may include, for example, an organic material, such as polyimide or HMDSO. The pixel-defining layer 130 may be omitted according to an embodiment.

The light-emitting diode layer DPL may be disposed on the pixel circuit layer PCL. The light-emitting diode layer DPL may include a display device layer 140 and a pixel electrode 210.

The display device layer 140 may include a plurality of light-emitting elements such as a first organic light-emitting diode OLED1, a second organic light-emitting diode OLED2, and a third organic light-emitting diode OLED3.

Each of The first to third organic light-emitting diodes OLED1 to OLED3 may include a stacked structure of the pixel electrode 210, an emission layer 220, and an opposite electrode 230. Each of the first to third organic light-emitting diodes OLED1 to OLED3 may emit light having the same peak spectrum as one another. In an embodiment, for example, each of the first to third organic light-emitting diodes OLED1 to OLED3 may emit white light. In an embodiment, for example, the peak spectrum of each of the first to third organic light-emitting diodes OLED1 to OLED3 may have a peak in a first wavelength band in a range of about 435 nanometers (nm) to about 490 nm, a second wavelength band in a range of about 500 nm to about 590 nm, and in a third wavelength band in a range of about 600 nm to about 710 nm. The first to third organic light-emitting diodes OLED1 to OLED3 may emit light, and the planar areas in which the light is emitted may be defined as first to third emission areas EA1, EA2, and EA3, respectively. While emission areas are indicated by the horizontal direction in FIG. 6, it will be understood that such direction may be defined along two directions crossing each other (e.g., two directions within an x-y plane).

A plurality of pixel electrodes 210 may be disposed on the via-insulating layer 120. The pixel electrodes 210 may be electrically connected to the transistor TR through a contact hole provided in the via-insulating layer 120. Each of the pixel electrodes 210 may include a transmissive conductive layer including transmissive conductive oxide such as ITO, In₂O₃, or IZO and a reflection layer including metal such as Al or Ag. In an embodiment, for example, each of the pixel electrodes 210 may have a triple-layered structure of ITO/Ag/ITO.

As illustrated in FIG. 6, the pixel electrodes 210 may include a first pixel electrode 210a, a second pixel electrode 210b, and a third pixel electrode 210c. The first to third pixel electrodes 210a to 210c may be arranged to be spaced apart from one another in a plan view, that is, when viewed in a direction perpendicular to the first substrate 100.

The emission layer 220 may be commonly disposed on the pixel electrodes 210. The emission layer 220 may be disposed on the via-insulating layer 120 to cover the pixel electrodes 210. According to an embodiment, the emission layer 220 may be integrally formed throughout the plurality of pixel electrodes 210. According to an embodiment, the emission layer 220 may be patterned to correspond to each of the plurality of pixel electrodes 210, respectively.

The emission layer 220 may emit light of a color. In an embodiment, for example, the emission layer 220 may emit white light. In an embodiment, for example, the emission layer 220 may have an emission spectrum having a peak in a first wavelength band in a range of about 435 nm to about 490 nm, a second wavelength band in a range of about 500 nm to about 590 nm, and a third wavelength band in a range of about 600 nm to about 710 nm.

According to an embodiment, the emission layer 220 may include a high molecular-weight or low molecular-weight organic material. The emission layer 220 may include an organic emission layer. In an embodiment, for example, the emission layer 220 may include a high molecular-weight material, such as a polyphenylene vinylene (PPV)-based material and a polyfluorene-based material. The emission layer 220 may be formed by using a screen printing method, an inkjet printing method, a laser induced thermal imaging (LITI) method, etc. However, the disclosure is not limited thereto. The emission layer 220 may include an inorganic light-emission material or quantum dots.

According to an embodiment, a functional layer (not shown) may be disposed both below and above the emission layer 220. The functional layer may include a hole injection layer (HIL), a hole transport layer (HTL), an electron transport layer (ETL), and/or an electron injection layer (EIL). The functional layer may be integrally formed (e.g., commonly disposed) throughout the plurality of pixel electrodes 210 or may be patterned to correspond to each of the plurality of pixel electrodes 210.

The opposite electrode 230 may be disposed on the pixel electrodes 210 and may overlap the pixel electrodes 210. The opposite electrode 230 may be disposed on the emission layer 220. The opposite electrode 230 may include a conductive material having a low work function. In an embodiment, for example, the opposite electrode 230 may include a (semi) transparent layer including Ag, Mg, Al, Pt, Pd, Au, Ni, Nd, Ir, Cr, Li, Ca, or an alloy thereof. Alternatively, the opposite electrode 230 may further include a layer, such as ITO, IZO, ZnO, or In₂O₃, on the (semi) transparent layer including the material described above. The opposite electrode 230 may be integrally formed to entirely cover the first substrate 100.

The pixel-defining layer 130 may include an opening 1300P defined therein and corresponding to the first to third sub-pixels PX1 to PX3. The opening 1300P of the pixel-defining layer 130 may expose at least a portion, for example, the central portion, of each of the pixel electrodes 210, to outside the pixel-defining layer 130. According to an embodiment, the first to third emission areas EA1 to EA3 may be defined as planar areas of an underlying layer (e.g., the pixel electrodes 210) respectively exposed by the opening 1300P of the pixel-defining layer 130.

A spacer (not shown) for preventing mask imprinting may further be provided on the pixel-defining layer 130. According to an embodiment, the spacer may be integrally formed with the pixel-defining layer 130. In an embodiment, for example, the spacer and the pixel-defining layer 130 may be simultaneously formed with each other by the same process using a half-tone mask process.

The encapsulation layer 300 may be disposed on the opposite electrode 230. The encapsulation layer 300 may be disposed to cover the first to third organic light-emitting diodes OLED1 to OLED3. The encapsulation layer 300 may include at least one inorganic encapsulation layer and at least one organic encapsulation layer. According to an embodiment, the encapsulation layer 300 may include a first inorganic encapsulation layer 310, an organic encapsulation layer 320 on the first inorganic encapsulation layer 310, and a second inorganic encapsulation layer 330.

The first inorganic encapsulation layer 310 and the second inorganic encapsulation layer 330 may include at least one inorganic material from among aluminum oxide, titanium oxide, tantalum oxide, hafnium oxide, ZnO, SiOₓ, SiNₓ, and SiON. The organic encapsulation layer 320 may include a polymer-based material. The polymer-based material may include acryl-based resins, epoxy-based resins, polyimide, polyethylene, etc. According to an embodiment, the organic encapsulation layer 320 may include acrylate. The organic encapsulation layer 320 may be formed by curing a monomer or by being coated with a polymer. The organic encapsulation layer 320 may be transparent.

The color filter layer 400 may be disposed on the encapsulation layer 300. The color filter layer 400 may include a first color filter 410, a second color filter 420, and a third color filter 430 transmitting light of different colors from one another, and a light-blocking portion BM, arranged in a direction along the encapsulation layer 300. The first to third color filters 410 to 430 may be disposed to correspond to the first to third sub-pixels PX1 to PX3, respectively. The first to third color filters 410 to 430 may be disposed to correspond to the pixel electrodes 210 of the first to third organic light-emitting diodes OLED1 to OLED3, respectively.

In an embodiment, for example, the first color filter 410 may be disposed to overlap the first pixel electrode 210a of the first organic light-emitting diode OLED1 in the direction (for example, a z-axis direction) perpendicular to the first substrate 100. In an embodiment, for example, the second color filter 420 may be disposed to overlap the second pixel electrode 210b of the second organic light-emitting diode OLED2 in the direction (for example, the z-axis direction) perpendicular to the first substrate 100. In an embodiment, for example, the third color filter 430 may be disposed to overlap the third pixel electrode 210c of the third organic light-emitting diode OLED3 in the direction (for example, the z-axis direction) perpendicular to the first substrate 100.

The first to third color filters 410 to 430 may include photosensitive resins. Each of the first to third color filters 410 to 430 may include a pigment or a dye representing a unique color. The first to third color filters 410 to 430 may transmit green light, red light, and blue light, respectively.

In an embodiment, for example, the first color filter 410 may be a green color filter selectively transmitting green light from the light emitted from the emission layer 220. In an embodiment, for example, the second color filter 420 may be a red color filter selectively transmitting red light from the light emitted from the emission layer 220. In an embodiment, for example, the third color filter 430 may be a blue color filter selectively transmitting blue light from the light emitted from the emission layer 220.

The light-blocking portion BM as a light-blocking pattern may be arranged between the first to third color filters 410 to 430. That is, the light-blocking portion BM may be arranged between the first color filter 410 and the second color filter 420 and between the second color filter 420 and the third color filter 430. The light-blocking portion BM may absorb light emitted by the first to third organic light-emitting diodes OLED1 to OLED3. Thus, a color mixture phenomenon of the light transmitted through the first to third color filters 410 to 430 may be reduced.

The MLA layer 500 may be disposed on the color filter layer 400. The MLA layer 500 may include a plurality of lenses 510. The plurality of lenses 510 may be disposed to overlap the first to third organic light-emitting diodes OLED1 to OLED, respectively, in the direction (for example, the z-axis direction) perpendicular to the first substrate 100. Each of the plurality of lenses 510 may have a predetermined curvature radius in cross-section and may refract the light emitted from each of the first to third organic light-emitting diodes OLED1 to OLED3. The MLA layer 500 may enlarge an image output from the display layer 200 and viewed from above the display apparatus 1.

The MLA layer 500 may include a glass material mainly including SiO₂ or may include resins such as reinforced plastics. Alternatively, the MLA layer 500 may include a glass substrate. FIG. 6 illustrates that the plurality of lenses 510 are connected to each other. However, it is only an example, and the plurality of lenses 510 may be arranged to be spaced apart from each other in a direction along the color filter layer 400.

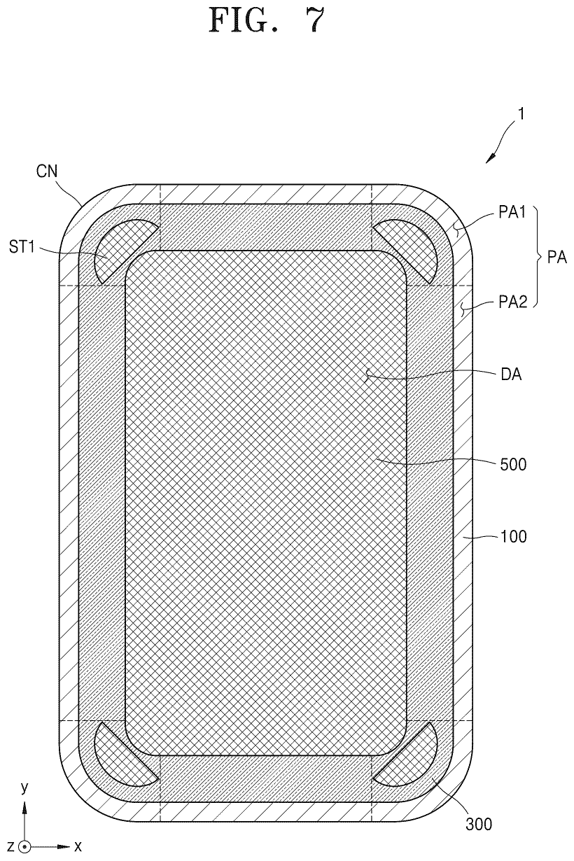

FIG. 7 is a schematic plan view of a portion of the display apparatus 1 according to an embodiment.

In detail, the display apparatus 1 illustrated in FIG. 7 may correspond to the lower portion PTD of the display apparatus 1 illustrated in FIGS. 4 and 5, while upper portion PTU is omitted for convenience of illustration.

Referring to FIGS. 4, 5, and 7, the display apparatus 1 may include the first substrate 100, the display layer 200 disposed on the first substrate 100, the encapsulation layer 300 disposed on the display layer 200, the color filter layer 400 disposed on the encapsulation layer 300, the MLA layer 500 disposed on the color filter layer 400, and the first structure ST1 disposed on the encapsulation layer 300.

In FIG. 7, in a plan view, since the display layer 200 overlaps the encapsulation layer 300, the display layer 200 is not visible, and since the color filter layer 400 overlaps the MLA layer 500, the color filter layer 400 is not visible.

In the plan view, the display apparatus 1 may have a polygonal shape. Thus, the display apparatus 1 may include a corner portion CN provided in plural a plurality of corner portions CN at which sides of the display apparatus 1 respectively meet. In an embodiment, for example, as illustrated in FIG. 7, when the display apparatus 1 has a quadrangular shape in the plan view, the display apparatus 1 may include four corner portions CN.

In this structure, the peripheral area PA may be arranged to surround the display area DA and may include a plurality of first peripheral areas PA1 and a plurality of second peripheral areas PA2. The plurality of first peripheral areas PA1 may include or correspond to the corner portions CN and may be spaced apart from each other along a periphery of the display apparatus 1. The plurality of second peripheral areas PA2 may connect first peripheral areas PA1 to each other, respectively, to define a continuous peripheral area PA extended along an outer edge of the display apparatus 1. In an embodiment, for example, as illustrated in FIG. 7, when the display apparatus 1 has the quadrangular shape in the plan view, with respect to the plurality of first peripheral areas PA1, there may be four first peripheral areas PA1, and with respect to the plurality of second peripheral areas PA2, there may be four second peripheral areas PA2. That is, a first peripheral area PA1 corresponds to a corner portion CN of the display apparatus 1, and a second peripheral area PA2 is connected to the first peripheral area PA1 and extends away from the corner portion CN. The filler pattern (e.g., the first structure ST1) which is protruded from the encapsulation layer 300 is in the first peripheral area PA1.

At least a portion of the first structure ST1 may be arranged in at least one of the plurality of first peripheral areas PA1. The first structure ST1 may be provided in a plural number. The plurality of first structures ST1 may be provided in the same number as the plurality of first peripheral areas PA1.

The plurality of first structures ST1 may be arranged in the plurality of first peripheral areas PA1, respectively. Any one of the plurality of first structures ST1 may be arranged in any one of the plurality of first peripheral areas PA1. In an embodiment, for example, as illustrated in FIG. 7, the plurality of first peripheral areas PA1 may include the four first peripheral areas PA1 and the plurality of first structures ST1 may include four first structures ST1. Any one of the four first structures ST1 may be arranged in any corresponding one of the four first peripheral areas PA1.

In an embodiment, for example, in the plan view, the first structure ST1 may include a semi-circular planar shape which is convex toward the corner portion CN (e.g., in a direction away from the display area DA). As illustrated in FIG. 7, the four first structures ST1 may include the semicircular planar shapes which are convex toward the four corner portions CN, respectively. However, it is only an example, and the planar shapes and the number of first structures ST1 are not limited thereto.

In a process in which the upper portion PTU and the lower portion PTD of the display apparatus 1 are coupled to each other, a material of the filling member 800 may be gradually spread from the display area DA (FIG. 4) in an outer direction toward the peripheral area PA of the display apparatus 1 (FIG. 5). Here, a distance from the central portion of the display apparatus 1 to the first peripheral area PA1 may be greater than a distance from the central portion of the display apparatus 1 to the second peripheral area PA2 at a corner portion CN. Thus, the filling member 800 which spreads from the display area DA may not completely fill the first peripheral area PA1, or the filling member 800 which spreads from the display area DA may spill out of the sealing member 700 at the second peripheral area PA2.

However, according to one or more embodiment, the first structure ST1 accounts for a substantial portion of the first peripheral area PA1 (e.g., a volume within the inner space at the first peripheral area PA1. Thus, the material of the filling member 800 may efficiently fill the space of the first peripheral area PA1 which is not occupied by the first structure ST1. Thus, in the process in which the upper portion PTU and the lower portion PTD are coupled to each other, the material of the filling member 800 may not spill out of the sealing member 700 and may efficiently fill the inner space formed by the first substrate 100, the second substrate 600, and the sealing member 700 at the first peripheral area PA1.

Taking FIGS. 4 to 6 together with FIG. 7, each first structure ST1 may be a discrete pattern protruded in a direction away from the first substrate 100. The protrusion of the first structure ST1 may contact (e.g., form an interface with) the underlying stacked structure of the lower portion PTD and may not contact the upper portion PTU to provide a volume of the inner space above the first structure ST1. The protrusion may have a tapered shape in cross-section, without being limited thereto. In the plan view, the protrusion of the first structure ST1 may be considered as extending along a boundary between the MLA layer 500 and the encapsulation layer 300.

Referring to FIG. 7, the first structure ST1 may be disposed only in the corner portion CN and include only one discrete pattern along a radial direction from the display area DA, but is not limited thereto. In embodiments, the first structure ST1 may include one or more of a discrete pattern entirely within the corner portion CN (e.g., the first peripheral area PA1), one or more of a discrete pattern entirely in the second peripheral area PA2, one or more of a discrete pattern extending from the corner portion CN and into the second peripheral area PA2, or a combination thereof. The first structure ST1 may include only one pattern along a radial direction from the display area DA, or more than one pattern along the radial direction from the display area DA.

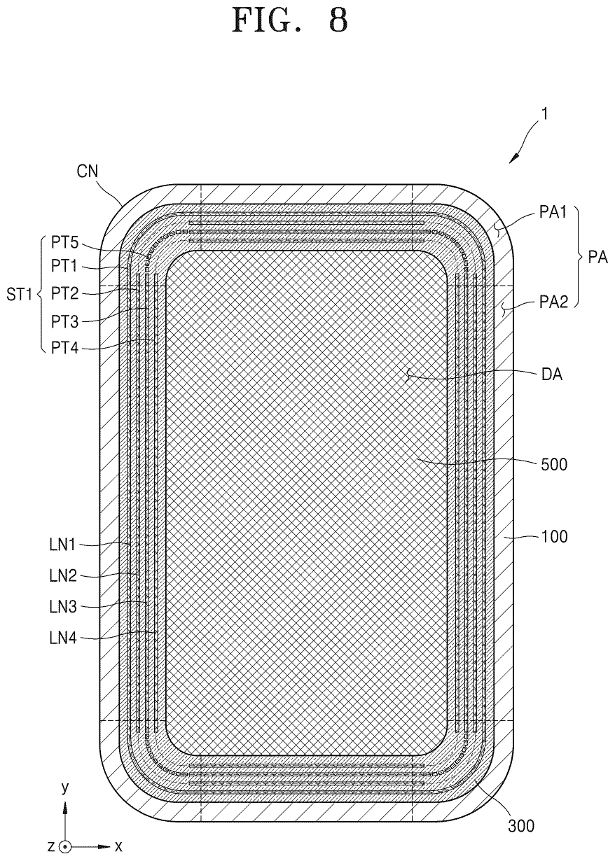

FIG. 8 is a schematic plan view of a portion of the display apparatus 1 according to an embodiment.

In detail, the display apparatus 1 illustrated in FIG. 8 may correspond to the lower portion PTD of the display apparatus 1 illustrated in FIGS. 4 and 5, while upper portion PTU is omitted for convenience of illustration.

Referring to FIGS. 4, 5, and 8, the display apparatus 1 may include the first substrate 100, the display layer 200 disposed on the first substrate 100, the encapsulation layer 300 disposed on the display layer 200, the color filter layer 400 disposed on the encapsulation layer 300, the MLA layer 500 disposed on the color filter layer 400, and the first structure ST1 disposed on the encapsulation layer 300.

In FIG. 8, in a plan view, since the display layer 200 overlaps the encapsulation layer 300, the display layer 200 is not visible, and since the color filter layer 400 overlaps the MLA layer 500, the color filter layer 400 is not visible.

In the plan view, the display apparatus 1 may have a polygonal planar shape. Thus, the display apparatus 1 may include a plurality of corner portions CN. In this structure, the peripheral area PA may be arranged to surround the display area DA and may include a plurality of first peripheral areas PA1 and a plurality of second peripheral areas PA2. The plurality of first peripheral areas PA1 may include the corner portions CN and may be spaced apart from each other. The plurality of second peripheral areas PA2 may be connected between the plurality of first peripheral areas PA1.

Here, a virtual line arranged in the peripheral area PA to surround the display area DA may be referred to as a first line LN1 (e.g., a first virtual line), a virtual line arranged in the peripheral area PA to surround the display area DA and apart from the first line LN1 may be referred to as a second line LN2 (e.g., a second virtual line), a virtual line arranged in the peripheral area PA to surround the display area DA and apart from the second line LN2 may be referred to as a third line LN3 (e.g., a third virtual line), and a virtual line arranged in the peripheral area PA to surround the display area DA and apart from the third line LN3 may be referred to as a fourth line LN4 (e.g., a fourth virtual line).

The first line LN1 may surround the second line LN2, the second line LN2 may surround the third line LN3, and the third line LN3 may surround the fourth line LN4. That is, the second line LN2 may be closer to the display area DA than the first line LN1, the third line LN3 may be closer to the display area DA than the second line LN2, and the fourth line LN4 may be closer to the display area DA than the third line LN3.

The first structure ST1 may include a first portion PT1 or first pattern extending along the first line LN1, a second portion PT2 or second pattern extending along the second line LN2, a third portion PT3 or third pattern extending along the third line LN3, and a fourth portion PT4 or fourth pattern extending along the fourth line LN4. As extending along, the various patterns may overlap a corresponding virtual line.

The first portion PT1, the second portion PT2, the third portion PT3, and the fourth portion PT4 may each be provided to have a thin linear shape extending in a lengthwise direction and may be arranged to be spaced apart from each other. The lengthwise direction (e.g., length) may be defined by a major dimension of a respective pattern in the plan view, and such pattern may have the major dimension thereof extended an extension direction.

The first portion PT1 may be integrally provided. The first portion PT1 may form a closed curve. That is, the first portion PT1 may be a single pattern which is continuous and extends along an entirety of the first line LN1.

The second portion PT2 may be provided in a plural number. That is, the second portion PT2 may be a plurality of (discrete) patterns spaced apart from each other along the second line LN2 and each being a continuous pattern. The plurality of second portions PT2 may be spaced apart from each other at or by at least one of the plurality of first peripheral areas PA1. In an embodiment, for example, the plurality of second portions PT2 may be spaced apart from or disconnected from each other at each of the plurality of first peripheral areas PA1. Ends of a discrete pattern of the second portion PT2 may extend from the second peripheral area PA2 and into opposing first peripheral areas PA1. At a same first peripheral area PA1 (or a same corner portion CN), no pattern of the second portion PT2 may be disposed between corresponding ends of respective discrete patterns ending at the same first peripheral area PA1. In this structure, the number of first peripheral areas PA1 may be the same as the number of second portions PT2. In an embodiment, for example, as illustrated in FIG. 8, each of the number of first peripheral areas PA1 and the number of second portions PT2 may be four.

The third portion PT3 may be provided in a plural number. Adjacent third portions PT3 may be spaced apart from or disconnected from each other in at least one of the plurality of first peripheral areas PA1. In an embodiment, for example, the plurality of third portions PT3 may be spaced apart from each other at each of the plurality of first peripheral areas PA1. In this structure, the number of first peripheral areas PA1 may be the same as the number of third portions PT3. In an embodiment, for example, as illustrated in FIG. 8, each of the number of first peripheral areas PA1 and the number of third portions PT3 may be four.

Similar to the second portion PT2 described above, the fourth portion PT4 may be provided in a plural number. The plurality of fourth portions PT4 may be spaced apart from each other in at least one of the plurality of first peripheral areas PA1. In an embodiment, for example, the plurality of fourth portions PT4 may be spaced apart from each other in each of the plurality of first peripheral areas PA1. In this structure, the number of first peripheral areas PA1 may be the same as the number of fourth portions PT4. In an embodiment, for example, as illustrated in FIG. 8, each of the number first peripheral areas PA1 and the number of fourth portions PT4 may be four.

A plurality of fifth portions PT5 may be arranged in at least one of the plurality of first peripheral areas PA1 along the third line LN3. In an embodiment, for example, the plurality of fifth portions PT5 may be arranged in each of the plurality of first peripheral areas PA1 along the third line LN3. The plurality of fifth portions PT5 may be spaced apart from each other. Also, the plurality of fifth portions PT5 may be spaced apart from the plurality of third portions PT3, respectively. All of the fifth portion PT5 for a same first peripheral area PA1 may be entirely within the same first peripheral area PA1. Owing to the first portion PT1 and the fifth portions PT5 in a same first peripheral area PA1, the first structure ST1 has a plurality of patterns disposed along a radial direction from the display area DA.

That is, for a same third line LN3, the third portion PT3 (as a second sub-pattern) may be a plurality of (discrete) patterns spaced apart from each other along the third line LN3 and each being a continuous pattern. Within a same first peripheral area PA1, the fifth portions PT5 (as first sub-patterns) may be a plurality of (discrete) patterns spaced apart from each other along the third line LN3 and each being a continuous pattern. Ends of a second sub-pattern may extend from the second peripheral area PA2 and into opposing first peripheral areas PA1. An entirety of the group of first sub-patterns may be between corresponding ends of respective second sub-patterns ending at the same first peripheral area PA1. The first and second sub-patterns may together provide a filler pattern of the first structure ST1 which are arranged corresponding to the third line LN3.

According to the present embodiment, each of the first portion PT1, the plurality of second portions PT2, the plurality of third portions PT3, and the plurality of fourth portions PT4 may perform a function of a dam of the filling member 800.

In detail, the first portion PT1 as an outermost filler pattern may perform the function of the dam of the filling member 800 throughout an entirety of the peripheral area PA. Thus, through surface tension and the capillary phenomenon of the filling member 800, the speed by which a material of the filling member 800 is spread from the display area DA to the first peripheral area PA1 and the second peripheral area PA2 may be stabilized.

Also, each of the plurality of second portions PT2, the plurality of third portions PT3, and the plurality of fourth portions PT4 each as an inner filler pattern may perform the function of the dam of the filling member 800 in the second peripheral area PA2. Thus, through surface tension and the capillary phenomenon of the filling member 800, the speed by which material of the filling member 800 is spread from the display area DA to the first peripheral area PA1 may be reduced compared to the speed by which a material of the filling member 800 is spread from the display area DA to the second peripheral area PA2. Thus, in the process in which the upper portion PTU and the lower portion PTD are coupled to each other, the filling member 800 may not spill out of the sealing member 700 and may efficiently fill the space formed by the first substrate 100, the second substrate 600, and the sealing member 700.

Also, due to the plurality of fifth portions PT5 as a corner filler pattern, a material of the filling member 800 may be efficiently spread from the display area DA to the first peripheral area PA1. That is, the material of the filling member 800 may be distributed in the first peripheral area PA1 by the plurality of fifth portions PT5 and may stably fill the first peripheral area PA1 due to the first portion PT1 occupying a volume of the inner space at the corner portion CN.

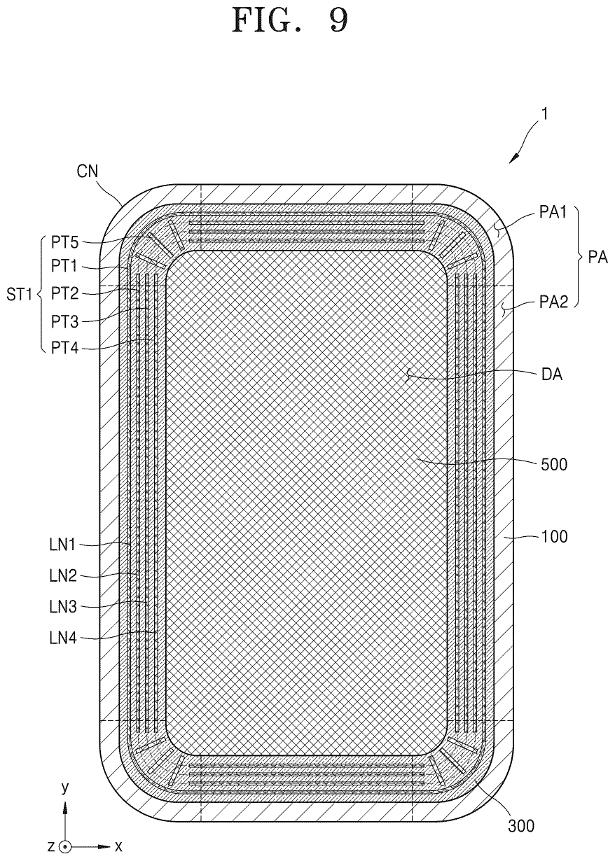

FIG. 9 is a schematic plan view of a portion of the display apparatus 1 according to an embodiment.

In detail, the display apparatus 1 illustrated in FIG. 9 may correspond to the lower portion PTD of the display apparatus 1 illustrated in FIGS. 4 and 5, while upper portion PTU is omitted for convenience of illustration.

Referring to FIGS. 4, 5, and 9, the display apparatus 1 may include the first substrate 100, the display layer 200 disposed on the first substrate 100, the encapsulation layer 300 disposed on the display layer 200, the color filter layer 400 disposed on the encapsulation layer 300, the MLA layer 500 disposed on the color filter layer 400, and the first structure ST1 disposed on the encapsulation layer 300.

In FIG. 9, in a plan view, since the display layer 200 overlaps the encapsulation layer 300, the display layer 200 is not visible, and since the color filter layer 400 overlaps the MLA layer 500, the color filter layer 400 is not visible.

In the plan view, the display apparatus 1 may have a polygonal planar shape. Thus, the display apparatus 1 may include a plurality of corner portions CN. In this structure, the peripheral area PA may be arranged to surround the display area DA and may include a plurality of first peripheral areas PA1 and a plurality of second peripheral areas PA2. The plurality of first peripheral areas PA1 may include the corner portions CN and may be spaced apart from each other. The plurality of second peripheral areas PA2 may be connected between the plurality of first peripheral areas PA1.

Here, a virtual line arranged in the peripheral area PA to surround the display area DA may be referred to as a first line LN1, a virtual line arranged in the peripheral area PA to surround the display area DA and apart from the first line LN1 may be referred to as a second line LN2, a virtual line arranged in the peripheral area PA to surround the display area DA and apart from the second line LN2 may be referred to as a third line LN3, and a virtual line arranged in the peripheral area PA to surround the display area DA and apart from the third line LN3 may be referred to as a fourth line LN4.

The first line LN1 may surround the second line LN2, the second line LN2 may surround the third line LN3, and the third line LN3 may surround the fourth line LN4. The first structure ST1 may include a first portion PT1 extending along the first line LN1, a second portion PT2 extending along the second line LN2, a third portion PT3 extending along the third line LN3, and a fourth portion PT4 extending along the fourth line LN4.

The first portion PT1 may be integrally provided. The first portion PT1 may form a closed curve.

The second portion PT2 may be provided in a plural number. The plurality of second portions PT2 may be spaced apart from each other in at least one of the plurality of first peripheral areas PA1. In an embodiment, for example, the plurality of second portions PT2 may be spaced apart from each other in each of the plurality of first peripheral areas PA1.

The third portion PT3 may be provided in a plural number. The plurality of third portions PT3 may be spaced apart from each other in at least one of the plurality of first peripheral areas PA1. In an embodiment, for example, the plurality of third portions PT3 may be spaced apart from each other in each of the plurality of first peripheral areas PA1.

The fourth portion PT4 may be provided in a plural number. The plurality of fourth portions PT4 may be spaced apart from each other in at least one of the plurality of first peripheral areas PA1. In an embodiment, for example, the plurality of fourth portions PT4 may be spaced apart from each other in each of the plurality of first peripheral areas PA1.

A plurality of fifth portions PT5 may be arranged in at least one of the plurality of first peripheral areas PA1. In an embodiment, for example, the plurality of fifth portions PT5 may be arranged in each of the plurality of first peripheral areas PA1. The plurality of fifth portions PT5 may be common to more than one virtual line and spaced apart from each other along such lines. Also, the plurality of fifth portions PT5 may be spaced apart from the plurality of second, third and fourth portions PT2, PT3 and PT4, respectively. All of the fifth portion PT5 for a same first peripheral area PA1 may be entirely within the same first peripheral area PA1. Owing to the first portion PT1 and the fifth portions PT5 in a same first peripheral area PA1, the first structure ST1 has a plurality of patterns disposed along a radial direction from the display area DA.

The plurality of fifth portions PT5 may extend in at least one of the plurality of first peripheral areas PA1 in a direction crossing each of the second line LN2, the third line LN3, and the fourth line LN4. The plurality of fifth portions PT5 may extend in each of the plurality of first peripheral areas PA1 in the direction crossing each of the second line LN2, the third line LN3, and the fourth line LN4.

Each of the plurality of fifth portions PT5 may be provided to have a thin linear shape extending in a lengthwise direction along the radial direction. The plurality of fifth portions PT5 may be spaced apart from each other in a direction crossing the radial direction. Also, the plurality of fifth portions PT5 may be spaced apart from each of the first portion PT1, the plurality of second portions PT2, the plurality of third portions PT3, and the plurality of fourth portions PT4.

The plurality of fifth portions PT5 may be arranged in a radial fashion relative to a center of the display apparatus 1, such as within the display area DA. FIG. 9 illustrates that with respect to the plurality of fifth portions PT5, three fifth portions PT5 are arranged in each of four first peripheral areas PA1. However, it is only an example, and the number and the arrangement of the plurality of fifth portions PT5 are not limited thereto.

According to the present embodiment, each of the first portion PT1, the plurality of second portions PT2, the plurality of third portions PT3, and the plurality of fourth portions PT4 may perform a function of a dam of the filling member 800.

In detail, the first portion PT1 may perform the function of the dam of the filling member 800 throughout the peripheral area PA. Thus, through surface tension and the capillary phenomenon of the filling member 800, the speed by which the filling member 800 is spread from the display area DA to the first peripheral area PA1 and the second peripheral area PA2 may be stabilized.

Also, each of the plurality of second portions PT2, the plurality of third portions PT3, and the plurality of fourth portions PT4 may perform the function of the dam of the filling member 800 in the second peripheral area PA2. Thus, through surface tension and the capillary phenomenon of the filling member 800, the speed by which the filling member 800 is spread from the display area DA to the first peripheral area PA1 may be reduced compared to the speed by which the filling member 800 is spread from the display area DA to the second peripheral area PA2. Thus, in the process in which the upper portion PTU and the lower portion PTD are coupled to each other, the filling member 800 may not spill out of the sealing member 700 and may efficiently fill the space formed by the first substrate 100, the second substrate 600, and the sealing member 700.

Also, due to the plurality of fifth portions PT5 defining a flow path along the radial direction, the filling member 800 may be efficiently spread from the display area DA to the first peripheral area PA1. That is, the filling member 800 may be distributed in the first peripheral area PA1 by the plurality of fifth portions PT5 and may stably fill the first peripheral area PA1 due to the first portion PT1.

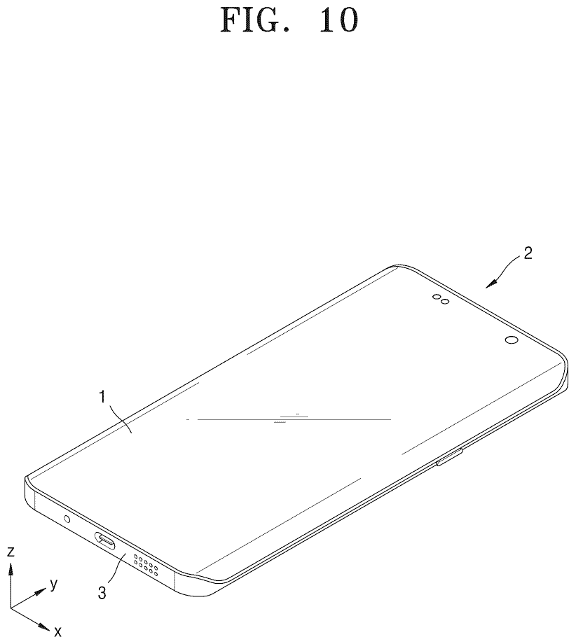

FIG. 10 is a schematic perspective view of an electronic device 2 according to an embodiment.

Referring to FIG. 10, the display apparatus 1 may be provided in the electronic device 2 and may display a video or a still image or may input and output data. In an embodiment, for example, the display apparatus 1 may be accommodated in a housing 3 of the electronic device 2. The housing 3 may be a component configured to protect elements of the electronic device 2 and fix the display apparatus 1.

FIG. 10 illustrates that the electronic device 2 is a mobile phone. However, the disclosure is not limited thereto. The electronic device 2 may include a portable electronic device, such as a laptop, a tablet personal computer (PC), a mobile phone, a smartphone, a mobile communication terminal, an electronic notebook, an electronic book, a portable multimedia player (PMP), a navigation device, an ultra mobile PC (UMPC), etc.

Alternatively, the electronic device 2 may include a television, a monitor, an advertisement board, an electronic device for the Internet of things (IoT), or a wearable electronic device such as a smart watch, a watch phone, a glasses-type display and a head mounted display (HMD). Also, the electronic device 2 according to an embodiment may be an electronic device for a display, such as a center information display (CID) on a gauge of a vehicle or a center fascia or a dashboard of the vehicle; a room mirror display substituting a side-view mirror of a vehicle; or a display disposed on a rear surface of a front seat, as an entertainment device for a backseat of a vehicle.

According to the one or more of the described embodiments, the display apparatus may have improved durability, a reduced defective rate, and a simplified manufacturing process.

However, the effects described above do not limit the scope of the disclosure.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by one of ordinary skill in the art that various changes in form and details may be made therein without departing from the spirit and scope as defined by the following claims.

What is claimed is:

1. A display apparatus comprising:
a first substrate comprising:
a display area including a pixel circuit layer and a light-emitting diode layer which is connected to the pixel circuit layer, and
a peripheral area adjacent to the display area;
an encapsulation layer which covers the pixel circuit layer and the light-emitting diode layer and extends to the peripheral area;
a filler pattern which is protruded from the encapsulation layer in a direction away from the first substrate, within the peripheral area;
a second substrate facing the first substrate with the encapsulation layer therebetween;
a sealing member which combines the first substrate to the second substrate, the sealing member together with the first substrate and the second substrate providing an inner space of the display apparatus in which the light-emitting diode layer, the pixel circuit layer, the encapsulation layer and the filler pattern are disposed; and
a filling member which fills the inner space.

2. The display apparatus of claim 1, wherein
the peripheral area comprises:
a first peripheral area corresponding to a corner portion of the display apparatus, and
a second peripheral area which is connected to the first peripheral area and extends away from the corner portion, and
the filler pattern which is protruded from the encapsulation layer is in the first peripheral area.

3. The display apparatus of claim 2, wherein in a plan view of the first substrate, the filler pattern has a semi-circular shape which is convex in a direction away from the display area.

4. The display apparatus of claim 2, wherein
the peripheral area includes virtual lines which surround the display area, the virtual lines comprising a first virtual line and a second virtual line which is closer to the display area than the first virtual line, and
the filler pattern which is protruded from the encapsulation layer in the first peripheral area comprises:
a first portion extending along the first virtual line; and
second portions extending along the second virtual line and spaced apart from each other in the first peripheral area.

5. The display apparatus of claim 4, wherein
the virtual lines further comprise a third virtual line which is closer to the display area than the second virtual line, and
the filler pattern further comprises third portions extending along the third virtual line and spaced apart from each other in the first peripheral area.

6. The display apparatus of claim 5, wherein
the virtual lines further comprise a fourth virtual line which is closer to the display area than the third virtual line, and
the filler pattern further comprises fourth portions extending along the fourth virtual line and spaced apart from each other in the first peripheral area.

7. The display apparatus of claim 5, wherein the filler pattern further comprises fifth portions arranged spaced apart from each other along the third virtual line, in the first peripheral area.

8. The display apparatus of claim 5, wherein the filler pattern further comprises fifth portions each extended crossing the second virtual line and the third virtual line, the fifth portions spaced apart from each other along each of the second virtual line and the third virtual line, in the first peripheral area.

9. The display apparatus of claim 1, further comprising a lens array layer comprising lenses arranged along the encapsulation layer, in the display area.

10. The display apparatus of claim 9, wherein the lenses and the filler pattern are respective portions of a same material layer on the first substrate.

11. A display apparatus comprising:
a display area and a peripheral area which is adjacent to the display area;
a lower stacked structure comprising:
a first substrate,
a display layer on the first substrate, in the display area,
an encapsulation layer on the display layer and extended from the display area to the peripheral area, and
a filler pattern which is protruded from the encapsulation layer, in the peripheral area; and
an upper stacked structure comprising:
a second substrate facing the first substrate,
a filling member extended from the second substrate and toward the first substrate, and
a sealing member which is adjacent to the filling member,
wherein the lower stacked structure is combined with the upper stacked structure by the sealing member and defines an inner space of the display apparatus in which the display layer, the encapsulation layer, the filler pattern and the filling member are disposed, and
wherein the filler pattern protrudes in a direction toward the second substrate and is spaced apart from the second substrate.

12. The display apparatus of claim 11, wherein
the peripheral area comprises:
a first peripheral area corresponding to a corner portion of the display apparatus,
a second peripheral area which is connected to the first peripheral area and extends away from the corner portion, and
the filler pattern protruded from the encapsulation layer and toward the second substrate, in the first peripheral area.

13. The display apparatus of claim 12, wherein in a plan view of the first substrate, the filler pattern has a semi-circular shape which is convex in a direction away from the display area.

14. The display apparatus of claim 12, wherein
the peripheral area includes virtual lines which surround the display area, the virtual lines comprising a first virtual line and a second virtual line which is closer to the display area than the first virtual line, and
the filler pattern which is protruded from the encapsulation layer in the first peripheral area comprises:
a first portion extending along the first virtual line; and
second portions extending along the second virtual line and spaced apart from each other in the first peripheral area.

15. The display apparatus of claim 14, wherein
the virtual lines further comprise a third virtual line which is closer to the display area than the second virtual line, and
the filler pattern further comprises third portions extending along the third virtual line and spaced apart from each other in the first peripheral area.

16. The display apparatus of claim 15, wherein
the virtual lines further comprise a fourth virtual line which is closer to the display area than the third virtual line, and
the filler pattern further comprises fourth portions extending along the fourth virtual line and spaced apart from each other in the first peripheral area.

17. The display apparatus of claim 15, wherein the filler pattern further comprises fifth portions arranged spaced apart from each other along the third virtual line, in the first peripheral area.

18. The display apparatus of claim 15, wherein the filler pattern further comprises fifth portions each extended crossing the second virtual line and the third virtual line, the fifth portions spaced apart from each other along each of the second virtual line and the third virtual line, in the first peripheral area.

19. The display apparatus of claim 11, further comprising a lens array layer comprising lenses arranged along the encapsulation layer, in the display area.

20. An electronic device comprising:
a display apparatus comprising:
a first substrate comprising:
a display area including a display layer, and
a peripheral area adjacent to the display area;
an encapsulation layer which covers the display layer and extends to the peripheral area;
a second substrate facing the first substrate with the encapsulation layer therebetween;
a sealing member which combines the first substrate to the second substrate, the sealing member together with the first substrate and the second substrate providing an inner space of the display apparatus in which the display layer and the encapsulation layer are disposed; and
a filler which completely fills the inner space, the filler comprising:
a filler pattern which is adjacent to the display layer and protruded from the encapsulation layer in a direction toward the second substrate, within the peripheral area, and
a filling member which fills a remainder of the inner space except for a volume occupied by the filler pattern.
